(19) United States
(12) Patent Application Publication
(10) Pub. No.: US 2022/0298601 A1
(43) Pub. Date: Sep. 22, 2022

(54) ONE-DIMENSIONAL CORALLOID NiS/Ni3S4@PPy@MoS2-BASED WAVE ABSORBER, AND PREPARATION METHOD AND USE THEREOF

(71) Applicant: Qingdao University of Technology, Qingdao (CN)

(72) Inventors: Mingliang Ma, Qingdao (CN); Yanyan Liu, Qingdao (CN); Zhouyu Tong, Qingdao (CN); Zijian Liao, Qingdao (CN); Yan Chen, Qingdao (CN); Rongzhen Wang, Qingdao (CN)

(73) Assignee: Qingdao University of Technology, Qingdao (CN)

(21) Appl. No.: 17/654,686

(22) Filed: Mar. 14, 2022

(30) Foreign Application Priority Data
Mar. 16, 2021 (CN) 202110282222.7

(51) Int. Cl. C22B 3/00; B03C 1/01; C09C 3/10; C09C 3/06; C22B 3/22; C01G 53/11

(52) U.S. Cl. CPC C22B 23/0461; B03C 1/01; C09C 3/10; C09C 3/063; C22B 3/22; C01G 53/11; B82Y 30/00

(57) ABSTRACT

The present disclosure belongs to the technical field of wave absorbing materials, and discloses a one-dimensional coralloid NiS/Ni₃S₄@PPy@MoS₂-based wave absorber, and a preparation method and use thereof. A preparation method of a one-dimensional coralloid NiS/Ni₃S₄@PPy@MoS₂-based wave absorber includes the following steps. Preparing one-dimensional Ni nanowires by a reduction method. Coating a layer of polypyrrole (PPy) on the Ni nanowires by an in-situ polymerization method using pyrrole as a monomer, to obtain Ni@PPy nanowires. Coating MoS₂ nanorods on the Ni@PPy nanowires by a hydrothermal synthesis method. Meanwhile, Ni as a sacrificial template is vulcanized into NiS/Ni₃S₄ to prepare the one-dimensional coralloid NiS/Ni₃S₄@PPy@MoS₂-based wave absorber. The wave absorber has a novel surface morphology and simple preparation process.

### CROSS REFERENCE TO RELATED APPLICATION

This patent application claims the benefit and priority of Chinese Patent Application No. 202110282222.7, filed on Mar. 16, 2021, the disclosure of which is incorporated by reference herein in its entirety.

### FIELD OF THE DISCLOSURE

The present disclosure belongs to the technical field of wave absorbing materials, in particular relates to a one-dimensional coralloid NiS/Ni₃S₄@PPy@MoS₂-based wave absorber, and a preparation method and use thereof.

### BACKGROUND

In recent years, due to the widespread use of electromagnetic equipment, electromagnetic wave radiation has gradually become a serious social problem. High-energy electromagnetic radiation has produced great adverse effects in both civilian and military fields. Interfering radio waves generated by gigahertz electromagnetic waves can seriously affect the communication between aircraft and base stations. In addition, prolonged exposure to gigahertz radio frequency radiation can damage the human body's immune system and develop other diseases. To solve these problems, there is an urgent need for efficient electromagnetic wave absorbers.

Wave absorbers with a single loss mechanism cannot meet the requirements of “thin, light, wide and strong” emphasized by impedance matching and wave absorbing materials, which makes composite wave absorbing materials with multiple loss mechanisms attract extensive attention. In addition to material composition, structural design is also a major direction in the study of wave absorbing materials. Due to the unique shape anisotropy and high surface-to-volume ratio, the one-dimensional structure enlarges the transmission path of electromagnetic waves inside materials, such that the electromagnetic waves are fully absorbed during the transmission to increase an attenuation effect. Most of MoS₂ in the reported literatures about wave absorbing are MoS₂ nanosheet. The MoS₂ nanosheets, due to a simple preparation method and desirable electrochemical performances, have received extensive attention of researchers. However, MoS₂ nanorods have a relatively complicated preparation method. There are few reports on the MoS₂ nanorods. In addition, there are also few reports of nickel sulfides in the field of microwave absorption.

Through the above analysis, the existing problems and defects in the prior art are as follows: most of the MoS₂ in the reported literatures about wave absorbing are nanosheet MoS₂. There are few reports on the MoS₂ nanorods. In addition, there are also few reports of nickel sulfides in the field of microwave absorption.

The difficulty of solving the above problems and defects is: the MoS₂ nanorods have a more complicated preparation method than that of the MoS₂ nanosheet due to the requirements of templates or additives such as surfactants. Moreover, in the field of microwave absorption, due to a unique flower-like structure to enhance the microwave loss ability, the MoS₂ nanosheet has received extensive attention. There are few literatures on the wave-absorbing ability of MoS₂ nanorods. In addition, there are also few reports of nickel sulfides in the field of microwave absorption.

The significance of solving the above problems and defects is: the present disclosure provides a method for preparing MoS₂ nanorods with simple steps and a low cost, which is different from a template method, a surfactant addition method and the like in the prior art, thereby enriching preparation methods of the MoS₂ nanorods. In addition, in the present disclosure, a one-dimensional nickel sulfide compound (NiS/Ni₃S₄) is prepared, with a novel structure different from the reported spherical or amorphous structures. This provides a new idea for preparation of novel nickel sulfides, as well as provides theoretical and technical supports for use of the nickel sulfide-based wave absorbers.

### SUMMARY

In view of this, the present disclosure provides a one-dimensional coralloid NiS/Ni₃S₄@PPy@MoS₂-based wave absorber, and a preparation method and use thereof.

The present disclosure provides a preparation method of a one-dimensional coralloid NiS/Ni₃S₄@PPy@MoS₂-based wave absorber, including the following steps: preparing one-dimensional Ni nanowires by a reduction method; coating a layer of polypyrrole (PPy) on the Ni nanowires by an in-situ polymerization method using pyrrole as a monomer, to obtain Ni@PPy nanowires; and coating MoS₂ nanorods on the Ni@PPy nanowires by a hydrothermal synthesis method.

Further, the preparation method of a one-dimensional coralloid NiS/Ni₃S₄@PPy@MoS₂-based wave absorber may include the following steps.

Step 1, preparation of the one-dimensional Ni nanowires: dissolving NaOH in ethylene glycol, stirring to obtain a solution, adding a hydrazine hydrate solution as a reducing agent to the solution, followed by continuous stirring; placing an obtained mixed solution in a constant-temperature water bath with an external magnetic field, followed by adding a NiCl₂.6H₂O ethylene glycol solution dropwise with a syringe; and after standing, collecting the Ni nanowires with a magnet, followed by washing with absolute ethanol and deionized water, and conducting freeze-drying.

Step 2, preparation of the one-dimensional Ni@PPy nanowires: dispersing sodium dodecylbenzenesulfonate (SDBS) and the pyrrole in the deionized water under sonication, and adding the Ni nanowires to an obtained mixture under the sonication; after mechanically stirring the mixture, adding a FeCl₃ aqueous solution; continuing to conduct aggregation; and separating a precipitate with the magnet, followed by washing and freeze-drying to obtain the Ni@PPy nanowires.

Step 3, preparation of the one-dimensional coralloid NiS/Ni₃S₄@PPy@MoS₂-based wave absorber: under ultrasonication, dissolving Na₂MoO₄ and thioacetamide in the deionized water, adding the Ni@PPy nanowires, and mechanically stirring an obtained mixed solution continuously; transferring the entire mixed solution to an autoclave for reaction; and after the reaction is completed, separating a precipitate and washing by centrifugation, followed by freeze-drying to obtain NiS/Ni₃S₄@PPy@MoS₂ nanowires.

Further, a preparation method of the one-dimensional Ni nanowires may include the following steps: dissolving 1.2 g of the NaOH in 35 mL of the ethylene glycol, stirring for 1 h to obtain the solution, adding 10 mL of the hydrazine hydrate solution as the reducing agent to the solution, followed by continuous stirring for 0.5 h; placing the obtained mixed solution in the constant-temperature water bath at 80° C. with the external magnetic field, followed by adding 15 mL of the NiCl₂.6H₂O ethylene glycol solution dropwise with the syringe; and after standing for 5 min, collecting the Ni nanowires with the magnet, followed by washing 3 times with the absolute ethanol and the deionized water, and conducting freeze-drying at −60° C.

Further, the preparation method of the one-dimensional Ni nanowires may include the following steps: adding 15 mL of the NiCl₂.6H₂O ethylene glycol solution dropwise with the syringe; and after standing for 5 min, collecting the Ni nanowires with the magnet, followed by washing 3 times with the absolute ethanol and the deionized water, and conducting freeze-drying at −60° C.

Further, a preparation method of the one-dimensional Ni@PPy nanowires may include the following steps: dispersing 0.013 g of the SDBS and 0.1 mL of the pyrrole in 50 mL of the deionized water under sonication, and adding 0.05 g to 0.07 g of the Ni nanowires to the obtained mixture under the sonication; after mechanically stirring the mixture for 2 h, adding 5 mL of the FeCl₃ aqueous solution; continuing to conduct aggregation for 2 h; and separating the precipitate with the magnet, followed by washing and freeze-drying at −60° C. to obtain the Ni@PPy nanowires.

Further, a preparation method of the one-dimensional coralloid NiS/Ni₃S₄@PPy@MoS₂-based wave absorber may include the following steps: under ultrasonication, dissolving 0.04 g to 0.08 g of the Na₂MoO₄ and 0.08 g to 0.16 g of the thioacetamide in 20 mL of the deionized water, adding 0.04 g of the Ni@PPy nanowires, and mechanically stirring the obtained mixed solution continuously for 30 min; transferring the entire mixed solution to the autoclave for reaction at 200° C. for 12 h; and after the reaction is completed, separating the precipitate and washing by centrifugation, followed by freeze-drying at 60° C. to obtain the NiS/Ni₃S₄@PPy@MoS₂ nanowires.

Further, the FeCl₃ aqueous solution may have a concentration of 0.29 mol/L; and the NiCl₂.6H₂O ethylene glycol solution may have a concentration of 0.1 mol/L.

In the present disclosure, these parameters are obtained through continuous testing and optimization through experiments, where the addition of the SDBS and pyrrole may affect the layer thickness and final performance of the PPy; and the amount of thioacetamide and Na₂MoO₄ may affect the microscopic morphology of MoS₂ and the final properties of the product. Experiments with the parameters in this scheme will result in an optimal PPy layer thickness and nanorod MoS₂.

The present disclosure further provides a one-dimensional coralloid NiS/Ni₃S₄@PPy@MoS₂-based wave absorber prepared by the preparation method of a one-dimensional coralloid NiS/Ni₃S₄@PPy@MoS₂-based wave absorber. The wave absorber is a functional filler that absorbs electromagnetic waves through internal loss components (including a dielectric loss type and a resistive loss type). The wave absorber is a black powder in physical properties, and then a one-dimensional composite coralloid core-shell wave absorbing material in microscopic properties.

The present disclosure further provides a method for improving wireless communication using the one-dimensional coralloid NiS/Ni₃S₄@PPy@MoS₂-based wave absorber.

The present disclosure further provides a method for improving communication between an aircraft and a base station using the one-dimensional coralloid NiS/Ni₃S₄@PPy@MoS₂-based wave absorber.

Combined with all the above technical solutions, the present disclosure has the advantages and positive effects as follows: in the present disclosure, the one-dimensional Ni nanowires are prepared by a chemical reduction method, the Ni nanowires are externally coated with the PPy layer, and the MoS₂ nanorods externally grow on the PPy layer. Meanwhile, Ni as a sacrificial template is vulcanized into NiS/Ni₃S₄ to prepare the one-dimensional coralloid NiS/Ni₃S₄@PPy@MoS₂-based wave absorber. The wave absorber has a novel surface morphology and simple preparation process.

In the present disclosure, the one-dimensional Ni nanowires are prepared by the reduction method, with a simple process and low cost. The diameter and surface morphology of the Ni nanowires may be controlled by adjusting the amount of raw materials. Ni nanowires are coated with a layer of PPy by in-situ polymerization method using pyrrole as a monomer to obtain a core-shell structure Ni@PPy. The conductive polymer PPy has a one-dimensional structure, which may induce directional electron transport, thereby improving electrical energy dissipation and improving microwave loss capability. The one-dimensional Ni@PPy nanowires are coated with the MoS₂ nanorods by a hydrothermal method. The MoS₂ nanorods are coralloid as a whole and have a novel structure, which is different from the MoS₂ nanosheets with a flower-like structure reported in other literatures. The coralloid surface intensifies the multiple reflection and scattering behaviors of incident electromagnetic waves, helping to prolong the transmission path of microwaves.

In the present disclosure, when the MoS₂ nanorods are coated by the hydrothermal method, the Ni nanowires are sulfided by thioacetamide to prepare the NiS/Ni₃S₄ nanowires, thereby further improving the dielectric loss capability of the wave absorber. In addition, the one-dimensional NiS/Ni₃S₄ nanowires have a novel structure different from the spherical or non-obvious NiS/Ni₃S₄ structures reported in existing literatures. The preparation method has a simple process and a low cost in required raw materials. Moreover, the prepared wave absorber has relatively novel overall structure and combination of the raw materials, as well as excellent wave absorbing properties, thereby providing a new idea for design and preparation of one-dimensional wave absorbing materials. The nanorod MoS₂ is prepared using a simple hydrothermal method, which is different from the template method and surfactant addition method in the prior art.

### BRIEF DESCRIPTION OF THE DRAWINGS

Illustrative embodiments of the present disclosure are described in detail below with reference to the attached drawing figures.

FIG. 1 shows a method for preparing a one-dimensional coralloid NiS/Ni₃S₄@PPy@MoS₂-based wave absorber according to an embodiment of the disclosure.

FIG. 2 shows a scanning electron microscope (SEM) image of products of each step of Example 1 provided by the present disclosure, where (a) and (b) are Ni nanowires, (c) and (d) are Ni@PPy nanowires, and (e) and (f) are coralloid NiS/Ni₃S₄@PPy@MoS₂ nanowires.

FIG. 3 shows an X-ray photoelectron spectroscopy (XPS) diagram of a product of Example 1 provided by the present disclosure, where (a) is a total spectrum, (b) is an N is spectrum, (c) is a Ni 2p spectrum, (d) is a Mo 3d spectrum, and (e) is an S 2p spectrum.

FIG. 4 shows a schematic diagram of electromagnetic parameters and wave absorption performance analysis of a coralloid NiS/Ni₃S₄@PPy@MoS₂ sample prepared in Example 1 provided by the present disclosure.

### DETAILED DESCRIPTION

The following describes some non-limiting exemplary embodiments of the invention with reference to the accompanying drawings. The described embodiments are merely a part rather than all of the embodiments of the invention. All other embodiments obtained by a person of ordinary skill in the art based on the embodiments of the disclosure shall fall within the scope of the disclosure.

the present disclosure provides a one-dimensional coralloid NiS/Ni₃S₄@PPy@MoS₂-based wave absorber, and a preparation method and use thereof. The present disclosure will be described in detail below in conjunction with the accompanying drawings.

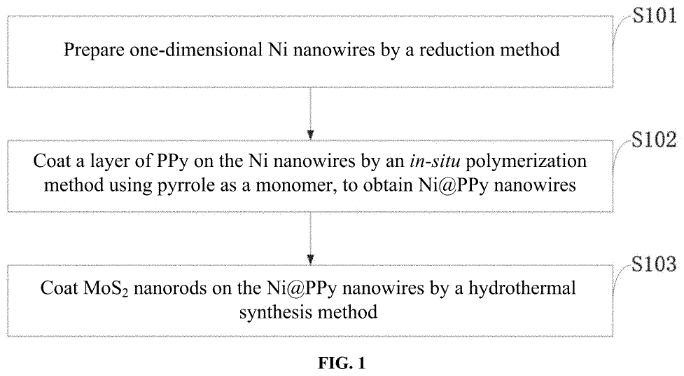

As shown in FIG. 1, the preparation method of a one-dimensional coralloid NiS/Ni₃S₄@PPy@MoS₂-based wave absorber includes the following steps:

S101: preparing one-dimensional Ni nanowires by a reduction method.

S102: coating a layer of PPy on the Ni nanowires by an in-situ polymerization method using pyrrole as a monomer, to obtain Ni@PPy nanowires.

S103: coating MoS₂ nanorods on the Ni@PPy nanowires by a hydrothermal synthesis method.

For the preparation method of a one-dimensional coralloid NiS/Ni₃S₄@PPy@MoS₂-based wave absorber provided by the present disclosure, those of ordinary skill in the art may also implement other steps. The preparation method of a one-dimensional coralloid NiS/Ni₃S₄@PPy@MoS₂-based wave absorber shown in FIG. 1 is only one example.

The technical solutions of the present disclosure will be further described below in conjunction with some examples.

The present disclosure provides a preparation method of a one-dimensional coralloid NiS/Ni₃S₄@PPy@MoS₂-based wave absorber. In this experiment, the one-dimensional Ni nanowires are prepared by reduction method, the Ni@PPy nanowires are coated with a layer of PPy by in-situ polymerization method using the pyrrole as a monomer, and the Ni@PPy nanowires are coated with a layer of MoS₂ nanorods by hydrothermal synthesis method. Meanwhile, the Ni as a sacrificial template is vulcanized into NiS/Ni₃S₄ to obtain the one-dimensional coralloid NiS/Ni₃S₄@PPy@MoS₂ wave absorber. The wave absorber has an excellent performance, novel structure and desirable prospect for use.

### Example 1

A preparation method of a one-dimensional coralloid NiS/Ni₃S₄@PPy@MoS₂-based wave absorber included the following steps:

(1) Preparation of one-dimensional Ni nanowires: 1.2 g of NaOH was dissolved in 35 mL of ethylene glycol, followed by stirring for 1 h to obtain a solution, 10 mL of a hydrazine hydrate solution as a reducing agent was added to the solution, followed by stirring for 0.5 h to obtain a mixed solution. The mixed solution was placed in a constant-temperature water bath at 80° C. with an external magnetic field, followed by adding 15 mL of a NiCl₂.6H₂O ethylene glycol solution (0.1 mol/L) dropwise to the mixed solution with a syringe. After standing for 5 min, Ni nanowires were collected with a magnet, followed by washing 3 times with absolute ethanol and deionized water, and freeze-drying was conducted at −60° C.

(2) Preparation of one-dimensional Ni@PPy nanowires: 0.013 g of SDBS and 0.1 mL of pyrrole were dispersed in 50 mL of the deionized water under sonication, and 0.07 g of the Ni nanowires were added to a resulting mixture under the sonication. After mechanically stirring the mixture for 2 h, 5 mL of a FeCl₃ aqueous solution (0.29 mol/L) was added, followed by continuing polymerization for another 2 h. A precipitate was separated with a magnet, followed by washing and freeze-drying at −60° C. to obtain the Ni@PPy nanowires.

(3) Preparation of a one-dimensional coralloid NiS/Ni₃S₄@PPy@MoS₂ wave absorber: under ultrasonication, 0.04 g of Na₂MoO₄ and 0.08 g of thioacetamide were dissolved in 20 mL of the deionized water, 0.04 g of the Ni@PPy nanowires were added, and a resulting mixed solution was continuously and mechanically stirred for 30 min. The entire mixed solution was transferred to an autoclave for reaction at 200° C. for 12 h. After the reaction was completed, a precipitate was separated and washed by centrifugation, followed by freeze-drying at −60° C. to obtain NiS/Ni₃S₄@PPy@MoS₂ nanowires.

### Example 2

A preparation method of a one-dimensional coralloid NiS/Ni₃S₄@PPy@MoS₂-based wave absorber included the following steps:

(1) Preparation of one-dimensional Ni nanowires: 1.2 g of NaOH was dissolved in 35 mL of ethylene glycol, followed by stirring for 1 h to obtain a solution, 10 mL of a hydrazine hydrate solution as a reducing agent was added to the solution, followed by stirring for 0.5 h to obtain a mixed solution. The mixed solution was placed in a constant-temperature water bath at 80° C. with an external magnetic field, followed by adding 15 mL of a NiCl₂.6H₂O ethylene glycol solution (0.1 mol/L) dropwise to the mixed solution with a syringe. After standing for 5 min, Ni nanowires were collected with a magnet, followed by washing 3 times with absolute ethanol and deionized water, and freeze-drying was conducted at −60° C.

(2) Preparation of one-dimensional Ni@PPy nanowires: 0.013 g of SDBS and 0.1 mL of pyrrole were dispersed in 50 mL of the deionized water under sonication, and 0.06 g of the Ni nanowires were added to a resulting mixture under the sonication. After mechanically stirring the mixture for 2 h, 5 mL of a FeCl₃ aqueous solution (0.29 mol/L) was added, followed by continuing polymerization for another 2 h. A precipitate was separated with a magnet, followed by washing and freeze-drying at −60° C. to obtain the Ni@PPy nanowires.

(3) Preparation of a one-dimensional coralloid NiS/Ni₃S₄@PPy@MoS₂ wave absorber: under ultrasonication, 0.04 g of Na₂MoO₄ and 0.08 g of thioacetamide were dissolved in 20 mL of the deionized water, 0.04 g of the Ni@PPy nanowires were added, and a resulting mixed solution was continuously and mechanically stirred for 30 min. The entire mixed solution was transferred to an autoclave for reaction at 200° C. for 12 h. After the reaction was completed, a precipitate was separated and washed by centrifugation, followed by freeze-drying at −60° C. to obtain NiS/Ni₃S₄@PPy@MoS₂ nanowires.

### Example 3

A preparation method of a one-dimensional coralloid NiS/Ni₃S₄@PPy@MoS₂-based wave absorber included the following steps:

(1) Preparation of one-dimensional Ni nanowires: 1.2 g of NaOH was dissolved in 35 mL of ethylene glycol, followed by stirring for 1 h to obtain a solution, 10 mL of a hydrazine hydrate solution as a reducing agent was added to the solution, followed by stirring for 0.5 h to obtain a mixed solution. The mixed solution was placed in a constant-temperature water bath at 80° C. with an external magnetic field, followed by adding 15 mL of a NiCl₂.6H₂O ethylene glycol solution (0.1 mol/L) dropwise to the mixed solution with a syringe. After standing for 5 min, Ni nanowires were collected with a magnet, followed by washing 3 times with absolute ethanol and deionized water, and freeze-drying was conducted at −60° C.

(2) Preparation of one-dimensional Ni@PPy nanowires: 0.013 g of SDBS and 0.1 mL of pyrrole were dispersed in 50 mL of the deionized water under sonication, and 0.05 g of the Ni nanowires were added to a resulting mixture under the sonication. After mechanically stirring the mixture for 2 h, 5 mL of a FeCl₃ aqueous solution (0.29 mol/L) was added, followed by continuing polymerization for another 2 h. A precipitate was separated with a magnet, followed by washing and freeze-drying at −60° C. to obtain the Ni@PPy nanowires.

(3) Preparation of a one-dimensional coralloid NiS/Ni₃S₄@PPy@MoS₂ wave absorber: under ultrasonication, 0.04 g of Na₂MoO₄ and 0.08 g of thioacetamide were dissolved in 20 mL of the deionized water, 0.04 g of the Ni@PPy nanowires were added, and a resulting mixed solution was continuously and mechanically stirred for 30 min. The entire mixed solution was transferred to an autoclave for reaction at 200° C. for 12 h. After the reaction was completed, a precipitate was separated and washed by centrifugation, followed by freeze-drying at −60° C. to obtain NiS/Ni₃S₄@PPy@MoS₂ nanowires.

### Example 4

A preparation method of a one-dimensional coralloid NiS/Ni₃S₄@PPy@MoS₂-based wave absorber included the following steps:

(1) Preparation of one-dimensional Ni nanowires: 1.2 g of NaOH was dissolved in 35 mL of ethylene glycol, followed by stirring for 1 h to obtain a solution, 10 mL of a hydrazine hydrate solution as a reducing agent was added to the solution, followed by stirring for 0.5 h to obtain a mixed solution. The mixed solution was placed in a constant-temperature water bath at 80° C. with an external magnetic field, followed by adding 15 mL of a NiCl₂.6H₂O ethylene glycol solution (0.1 mol/L) dropwise to the mixed solution with a syringe. After standing for 5 min, Ni nanowires were collected with a magnet, followed by washing 3 times with absolute ethanol and deionized water, and freeze-drying was conducted at −60° C.

(2) Preparation of one-dimensional Ni@PPy nanowires: 0.013 g of SDBS and 0.1 mL of pyrrole were dispersed in 50 mL of the deionized water under sonication, and 0.05 g of the Ni nanowires were added to a resulting mixture under the sonication. After mechanically stirring the mixture for 2 h, 5 mL of a FeCl₃ aqueous solution (0.29 mol/L/L) was added, followed by continuing polymerization for another 2 h. A precipitate was separated with a magnet, followed by washing and freeze-drying at −60° C. to obtain the Ni@PPy nanowires.

(3) Preparation of a one-dimensional coralloid NiS/Ni₃S₄@PPy@MoS₂ wave absorber: under ultrasonication, 0.06 g of Na₂MoO₄ and 0.12 g of thioacetamide were dissolved in 20 mL of the deionized water, 0.04 g of the Ni@PPy nanowires were added, and a resulting mixed solution was continuously and mechanically stirred for 30 min. The entire mixed solution was transferred to an autoclave for reaction at 200° C. for 12 h. After the reaction was completed, a precipitate was separated and washed by centrifugation, followed by freeze-drying at −60° C. to obtain NiS/Ni₃S₄@PPy@MoS₂ nanowires.

### Example 5

A preparation method of a one-dimensional coralloid NiS/Ni₃S₄@PPy@MoS₂-based wave absorber included the following steps:

(1) Preparation of one-dimensional Ni nanowires: 1.2 g of NaOH was dissolved in 35 mL of ethylene glycol, followed by stirring for 1 h to obtain a solution, 10 mL of a hydrazine hydrate solution as a reducing agent was added to the solution, followed by stirring for 0.5 h to obtain a mixed solution. The mixed solution was placed in a constant-temperature water bath at 80° C. with an external magnetic field, followed by adding 15 mL of a NiCl₂.6H₂O ethylene glycol solution (0.1 mol/L) dropwise to the mixed solution with a syringe. After standing for 5 min, Ni nanowires were collected with a magnet, followed by washing 3 times with absolute ethanol and deionized water, and freeze-drying was conducted at −60° C.

(2) Preparation of one-dimensional Ni@PPy nanowires: 0.013 g of SDBS and 0.1 mL of pyrrole were dispersed in 50 mL of the deionized water under sonication, and 0.05 g of the Ni nanowires were added to a resulting mixture under the sonication. After mechanically stirring the mixture for 2 h, 5 mL of a FeCl₃ aqueous solution (0.29 mol/L) was added, followed by continuing polymerization for another 2 h. A precipitate was separated with a magnet, followed by washing and freeze-drying at −60° C. to obtain the Ni@PPy nanowires.

(3) Preparation of a one-dimensional coralloid NiS/Ni₃S₄@PPy@MoS₂ wave absorber: under ultrasonication, 0.08 g of Na₂MoO₄ and 0.16 g of thioacetamide were dissolved in 20 mL of the deionized water, 0.04 g of the Ni@PPy nanowires were added, and a resulting mixed solution was continuously and mechanically stirred for 30 min. The entire mixed solution was transferred to an autoclave for reaction at 200° C. for 12 h. After the reaction was completed, a precipitate was separated and washed by centrifugation, followed by freeze-drying at −60° C. to obtain NiS/Ni₃S₄@PPy@MoS₂ nanowires.

### Example 6

A preparation method of a one-dimensional coralloid NiS/Ni₃S₄@PPy@MoS₂-based wave absorber included the following steps:

(1) Preparation of one-dimensional Ni nanowires: 1.2 g of NaOH was dissolved in 35 mL of ethylene glycol, followed by stirring for 1 h to obtain a solution, 10 mL of a hydrazine hydrate solution as a reducing agent was added to the solution, followed by stirring for 0.5 h to obtain a mixed solution. The mixed solution was placed in a constant-temperature water bath at 80° C. with an external magnetic field, followed by adding 15 mL of a NiCl₂.6H₂O ethylene glycol solution (0.1 mol/L) dropwise to the mixed solution with a syringe. After standing for 5 min, Ni nanowires were collected with a magnet, followed by washing 3 times with absolute ethanol and deionized water, and freeze-drying was conducted at −60° C.

(2) Preparation of one-dimensional Ni@PPy nanowires: 0.013 g of SDBS and 0.1 mL of pyrrole were dispersed in 50 mL of the deionized water under sonication, and 0.05 g of the Ni nanowires were added to a resulting mixture under the sonication. After mechanically stirring the mixture for 2 h, 5 mL of a FeCl₃ aqueous solution (0.29 mol/L) was added, followed by continuing polymerization for another 2 h. A precipitate was separated with a magnet, followed by washing and freeze-drying at −60° C. to obtain the Ni@PPy nanowires.

(3) Preparation of a one-dimensional coralloid NiS/Ni₃S₄@PPy@MoS₂ wave absorber: under ultrasonication, 0.1 g of ammonium molybdate and 0.2 g of thiourea were dissolved in 20 mL of the deionized water, 0.04 g of the Ni@PPy nanowires were added, and a resulting mixed solution was continuously and mechanically stirred for 30 min. The entire mixed solution was transferred to an autoclave for reaction at 200° C. for 12 h. After the reaction was completed, a precipitate was separated and washed by centrifugation, followed by freeze-drying at −60° C. to obtain NiS/Ni₃S₄@PPy@MoS₂ nanowires.

The technical effects of the disclosure will be described in detail below in conjunction with the accompanying drawings.

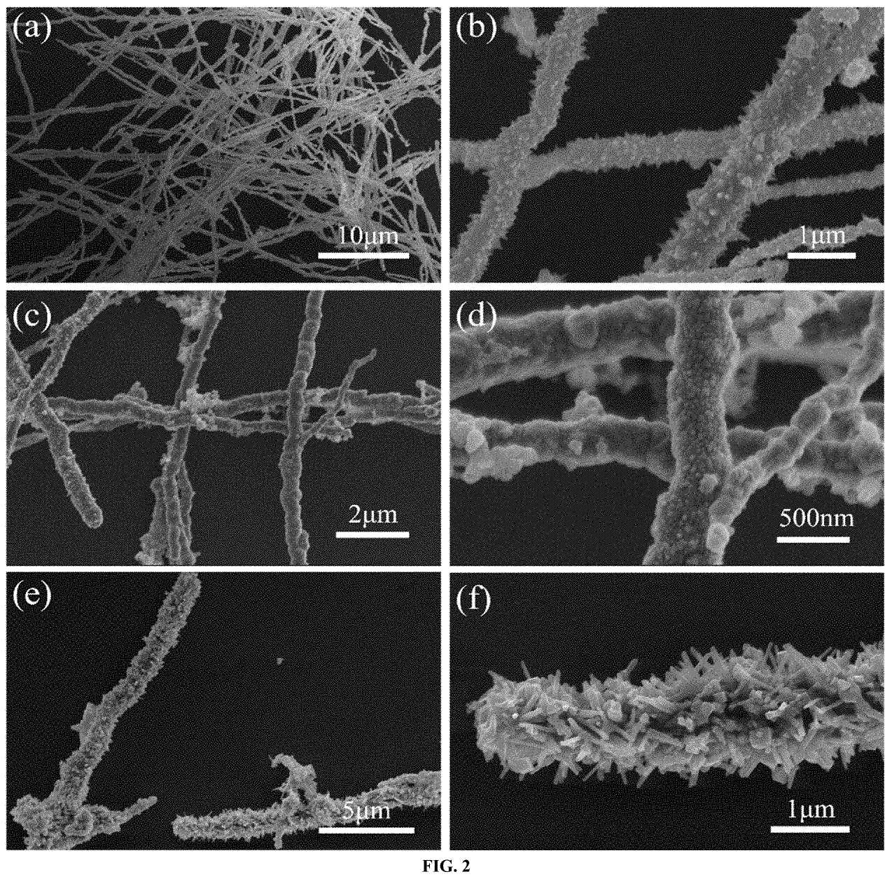

FIG. 2 shows a SEM image of products of each step of Example 1, where (a) and (b) are Ni nanowires, (c) and (d) are Ni@PPy nanowires, and (e) and (f) are coralloid NiS/Ni₃S₄@PPy@MoS₂ nanowires.

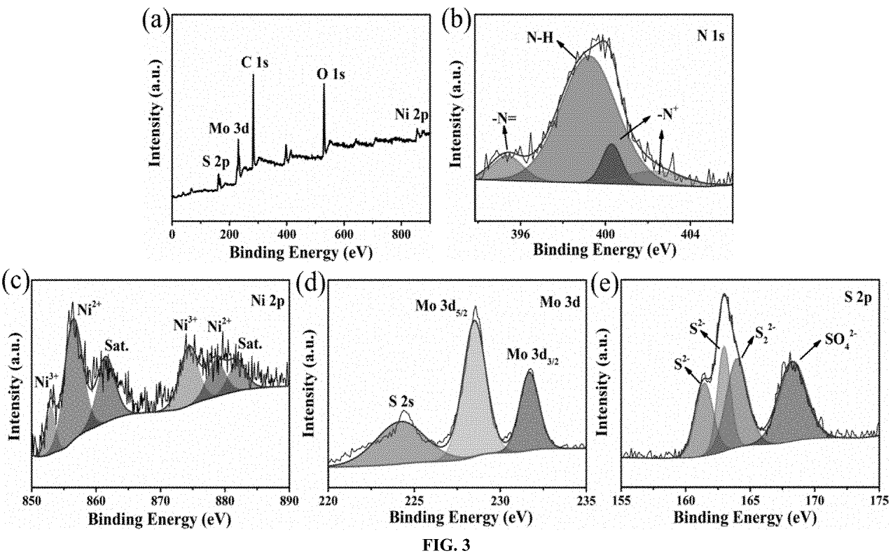

FIG. 3 shows an XPS diagram of a product of Example 1, where (a) is a total spectrum, (b) is an N is spectrum, (c) is a Ni 2p spectrum, (d) is a Mo 3d spectrum, and (e) is an S 2p spectrum.

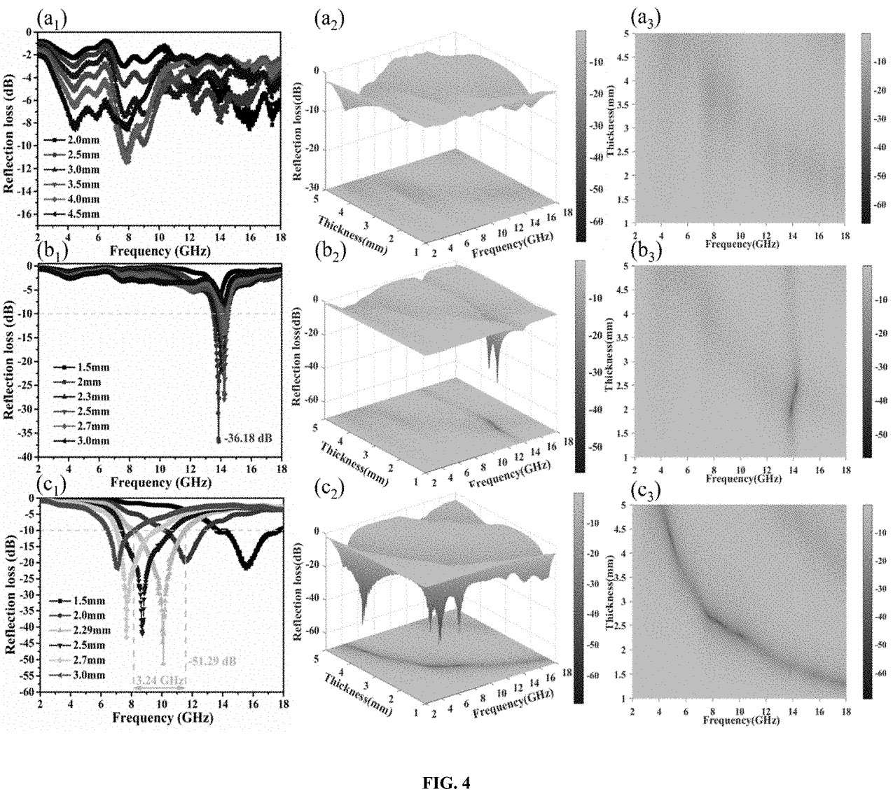

In the present disclosure, the electromagnetic parameters and wave-absorbing properties of the coralloid NiS/Ni₃S₄@PPy@MoS₂ samples with different doping (30%, 40% and 50%) prepared in Example 1 were analyzed using a vector network analyzer, and the results were shown in FIG. 4. In the FIG. 4, (c₁) (c₂) (c₃) in are reflection loss curves and three-dimensional reflection loss diagrams of the coralloid NiS/Ni₃S₄@PPy@MoS₂ samples with 50% doping prepared in Example 1 under different thicknesses. From (c₁) in FIG. 4, it can be found that when the thickness is 2.29 mm, the wave absorber has an optimal absorption performance, with a minimum reflection loss of −51.29 dB, a corresponding frequency of 10.1 GHz, an effective absorption bandwidth of less than −10 dB of 3.24 GHz, which shows an excellent absorption performance.

The foregoing are merely descriptions of the specific embodiments of the present disclosure, and the protection scope of the present disclosure is not limited thereto. Any modification, equivalent replacement, improvement, etc. made within the technical scope of the present disclosure by a person skilled in the art according to the spirit and principle of the present disclosure shall fall within the protection scope of the present disclosure.

Many different arrangements of the various components depicted, as well as components not shown, are possible without departing from the spirit and scope of the present disclosure. Embodiments of the present disclosure have been described with the intent to be illustrative rather than restrictive. Alternative embodiments will become apparent to those skilled in the art that do not depart from its scope. A skilled artisan may develop alternative means of implementing the aforementioned improvements without departing from the scope of the present disclosure.

It will be understood that certain features and subcombinations are of utility and may be employed without reference to other features and subcombinations and are contemplated within the scope of the claims. Unless indicated otherwise, not all steps listed in the various figures need be carried out in the specific order described.

The disclosure claimed is:

1. A method for preparing a one-dimensional coralloid NiS/Ni₃S₄@PPy@MoS₂-based wave absorber, comprising the steps of:
(1) preparing one-dimensional Ni nanowires by a reduction method;
(2) coating the Ni nanowires with a layer of polypyrrole (PPy) by an in-situ polymerization method using pyrrole as a monomer to obtain Ni@PPy nanowires; and
(3) coating the Ni@PPy nanowires with MoS₂ nanorods by a hydrothermal synthesis method.

2. The method according to claim 1, wherein:
step (1) comprises the steps of:
dissolving NaOH in ethylene glycol, stirring to obtain a solution, adding a hydrazine hydrate solution as a reducing agent to the solution, followed by continuous stirring;
placing an obtained mixed solution in a constant-temperature water bath with an external magnetic field, followed by adding a NiCl₂.6H₂O ethylene glycol solution dropwise with a syringe; and
after standing, collecting the Ni nanowires with a magnet, followed by washing with absolute ethanol and deionized water, and conducting freeze-drying;
step (2) comprises the steps of:
dispersing sodium dodecylbenzenesulfonate (SDBS) and the pyrrole in the deionized water under sonication, and adding the Ni nanowires to an obtained mixture under the sonication;
after mechanically stirring the mixture, adding a FeCl₃ aqueous solution;
continuing to conduct aggregation;
separating a precipitate with the magnet, followed by washing and freeze-drying to obtain the Ni@PPy nanowires; and
step (3) comprises the steps of:
under ultrasonication, dissolving Na₂MoO₄ and thioacetamide in the deionized water, adding the Ni@PPy nanowires, and mechanically stirring an obtained mixed solution continuously;
transferring the entire mixed solution to an autoclave for reaction; and
after the reaction is completed, separating a precipitate, and washing by centrifugation, followed by freeze-drying to obtain NiS/Ni₃S₄@PPy@MoS₂ nanowires.

3. The method according to claim 2, wherein the step (1) comprises:
dissolving 1.2 g of the NaOH in 35 mL of the ethylene glycol, stirring for 1 h to obtain the solution, adding 10 mL of the hydrazine hydrate solution as the reducing agent to the solution, followed by continuous stirring for 0.5 h;
placing the obtained mixed solution in the constant-temperature water bath at 80° C. with the external magnetic field, followed by adding 15 mL of the NiCl₂.6H₂O ethylene glycol solution dropwise with the syringe;
after standing for 5 min, collecting the Ni nanowires with the magnet, followed by washing 3 times with the absolute ethanol and the deionized water, and conducting freeze-drying at −60° C.

4. The method according to claim 2, wherein the step (1) comprises:
adding 15 mL of the NiCl₂.6H₂O ethylene glycol solution dropwise with the syringe; and
after standing for 5 min, collecting the Ni nanowires with the magnet, followed by washing 3 times with the absolute ethanol and the deionized water, and conducting freeze-drying at −60° C.

5. The method according to claim 2, wherein the step (2) comprises:
dispersing 0.013 g of the SDBS and 0.1 mL of the pyrrole in 50 mL of the deionized water under sonication, and adding 0.05 g to 0.07 g of the Ni nanowires to the obtained mixture under the sonication;
after mechanically stirring the mixture for 2 h, adding 5 mL of the FeCl₃ aqueous solution;
continuing to conduct aggregation for 2 h; and
separating the precipitate with the magnet, followed by washing and freeze-drying at −60° C. to obtain the Ni@PPy nanowires.

6. The method according to claim 2, wherein the step (3) comprises:
under ultrasonication, dissolving 0.04 g to 0.08 g of the Na₂MoO₄ and 0.08 g to 0.16 g of the thioacetamide in 20 mL of the deionized water, adding 0.04 g of the Ni@PPy nanowires, and mechanically stirring the obtained mixed solution continuously for 30 min;
transferring the entire mixed solution to the autoclave for reaction at 200° C. for 12 h; and
after the reaction is completed, separating the precipitate and washing by centrifugation, followed by freeze-drying at 60° C. to obtain the NiS/Ni₃S₄@PPy@MoS₂ nanowires.

7. The method according to claim 2, wherein:
the FeCl₃ aqueous solution has a concentration of 0.29 mol/L; and
the NiCl₂.6H₂O ethylene glycol solution has a concentration of 0.1 mol/L.

8. A one-dimensional coralloid NiS/Ni₃S₄@PPy@MoS₂-based wave absorber prepared by the method according to claim 1.

9. The wave absorber according to claim 8, wherein:
step (1) comprises the steps of:
dissolving NaOH in ethylene glycol, stirring to obtain a solution, adding a hydrazine hydrate solution as a reducing agent to the solution, followed by continuous stirring;
placing an obtained mixed solution in a constant-temperature water bath with an external magnetic field, followed by adding a NiCl₂.6H₂O ethylene glycol solution dropwise with a syringe; and
after standing, collecting the Ni nanowires with a magnet, followed by washing with absolute ethanol and deionized water, and conducting freeze-drying;
step (2) comprises the steps of:
dispersing sodium dodecylbenzenesulfonate (SDBS) and the pyrrole in the deionized water under sonication, and adding the Ni nanowires to an obtained mixture under the sonication;
after mechanically stirring the mixture, adding a FeCl₃ aqueous solution;
continuing to conduct aggregation; and
separating a precipitate with the magnet, followed by washing and freeze-drying to obtain the Ni@PPy nanowires; and
step (3) comprises the steps of:
under ultrasonication, dissolving Na₂MoO₄ and thioacetamide in the deionized water, adding the Ni@PPy nanowires, and mechanically stirring an obtained mixed solution continuously;
transferring the entire mixed solution to an autoclave for reaction; and
after the reaction is completed, separating a precipitate and washing by centrifugation, followed by freeze-drying to obtain NiS/Ni₃S₄@PPy@MoS₂ nanowires.

10. The wave absorber according to claim 9, wherein the step (1) comprises:
dissolving 1.2 g of the NaOH in 35 mL of the ethylene glycol, stirring for 1 h to obtain the solution, adding 10 mL of the hydrazine hydrate solution as the reducing agent to the solution, followed by continuous stirring for 0.5 h;
placing the obtained mixed solution in the constant-temperature water bath at 80° C. with the external magnetic field, followed by adding 15 mL of the NiCl₂.6H₂O ethylene glycol solution dropwise with the syringe; and
after standing for 5 min, collecting the Ni nanowires with the magnet, followed by washing 3 times with the absolute ethanol and the deionized water, and conducting freeze-drying at −60° C.

11. The wave absorber according to claim 9, wherein the step (1) comprises:
adding 15 mL of the NiCl₂.6H₂O ethylene glycol solution dropwise with the syringe; and
after standing for 5 min, collecting the Ni nanowires with the magnet, followed by washing 3 times with the absolute ethanol and the deionized water, and conducting freeze-drying at −60° C.

12. The wave absorber according to claim 9, wherein the step (2) comprises:
dispersing 0.013 g of the SDBS and 0.1 mL of the pyrrole in 50 mL of the deionized water under sonication, and adding 0.05 g to 0.07 g of the Ni nanowires to the obtained mixture under the sonication;
after mechanically stirring the mixture for 2 h, adding 5 mL of the FeCl₃ aqueous solution; continuing to conduct aggregation for 2 h; and
separating the precipitate with the magnet, followed by washing and freeze-drying at −60° C. to obtain the Ni@PPy nanowires.

13. The wave absorber according to claim 9, wherein the step (3) comprises:
under ultrasonication, dissolving 0.04 g to 0.08 g of the Na₂MoO₄ and 0.08 g to 0.16 g of the thioacetamide in 20 mL of the deionized water, adding 0.04 g of the Ni@PPy nanowires, and mechanically stirring the obtained mixed solution continuously for 30 min;
transferring the entire mixed solution to the autoclave for reaction at 200° C. for 12 h; and
after the reaction is completed, separating the precipitate and washing by centrifugation, followed by freeze-drying at 60° C. to obtain the NiS/Ni₃S₄@PPy@MoS₂ nanowires.

14. The wave absorber according to claim 9, wherein:
the FeCl₃ aqueous solution has a concentration of 0.29 mol/L; and
the NiCl₂.6H₂O ethylene glycol solution has a concentration of 0.1 mol/L.

15. A method for improving wireless communication, comprising the step of using the wave absorber according to claim 8.
